(19) United States
(12) Patent Application Publication
(10) Pub. No.: US 2008/0266016 A1
(43) Pub. Date: Oct. 30, 2008

(54) Semiconductor Switch with Integrated Delay Circuit

(75) Inventors: Gunter Uhl, Helmstadt-Bargen (DE); Steffen Wandres, Kandel (DE)

Correspondence Address: BOYLE FREDRICKSON S.C., 840 North Plankinton Avenue, MILWAUKEE, WI, 53203, US

(73) Assignee: CATEM DEVELEC GMBH & CO. KG, Herxheim, DE (DE)

(21) Appl. No.: 12/107,322

(22) Filed: Apr. 22, 2008

(30) Foreign Application Priority Data
Apr. 24, 2007 (EP) 07008356.3

(51) Int. Cl. H03K 7/08

(52) U.S. Cl. 332/110

(57) ABSTRACT

For controlling a multi-stage load with pulsewidth modulation (PWM), the individual stages have normally separately applied thereto load currents which are clocked in a phase-shifted mode so as to avoid load peaks. An output stage for PWM control of a load stage with a delay circuit which, in addition to the load current modulated by a PWM input signal, supplies a PWM output signal that is delayed by a predetermined fraction of the period duration relative to the PWM input signal. The output stage can especially be realized by integrating the delay circuit together with the actual power semiconductor switch and an associated monitoring and control circuit in a single component. By cascading such output stages, a controller for phase-shifted PWM control of multi-stage loads, which is independent of a precise time base, can be realized in a simple manner.

### BACKGROUND OF THE INVENTION

1. Field of the Invention

The present invention relates to a semiconductor switch with an integrated delay circuit, a controller for pulsewidth-modulated control of a multistage electric load and to a corresponding method.

2. Description of the Related Art

The control of the power consumption of an electric load, such as e.g. electric heatings, filament lamps, DC motors, etc., can be effected in a conventional manner through pulsewidth modulation (PWM). The supply voltage is in this case switched on and off at periodic intervals. The power consumption of the load can be controlled continuously via the duty cycle, i.e. the ratio of the on-time Tₒₙ within a period to the period duration T_{PWM} (cf. FIG. 1). The on-time Tₒₙ=0 represents the OFF state, the on-time Tₒₙ=T_{PWM} means constantly ON, i.e. maximum power. In comparison with a linear control of the supply voltage or of the current, e.g. by means of a series transistor, the power losses occurring at the transistors of the output stage can be reduced substantially in this way.

The devices used as output or switching stages of a PWM control, i.e. as semiconductor switches for high currents, are preferably MOSFETs which are either controlled and protected against overload (overcurrent, overvoltage and excess temperature) by their external additional circuitry or which already comprise this necessary additional circuitry in their housing. Such a protected output stage, which is often also referred to as smart power high-side-switch and which is commercially available e.g. from International Rectifier, is shown in FIG. 2. The internal structural design of such an output stage 200 consists of two semiconductor chips: the actual semiconductor switch (MOSFET) 202 and a control and monitoring circuit 201. The two chips are arranged side by side or one on top of the other. Monolithic solutions (all the functions on one semiconductor chip) are not very common in the case of high switching currents (several 10 A).

A PMW control of high-current loads, in particular of high-current loads in a vehicle electrical system, such as an electric auxiliary heating system or the glow plugs of an Diesel engine, is disadvantageous with regard to the load peaks which occur due to the clocking and which may become noticeable e.g. by an unpleasant flickering of the passenger compartment illumination, and with regard to the EMC problems (EMC: electromagnetic compatibility) entailed by the switching processes.

European patent EP 1 157 869 B1 discloses that a multi-stage electric auxiliary heating device for motor vehicles is controlled by means of pulsewidth modulation in such a way that only one heating stage at a time is driven by a current rise or fall.

Electric auxiliary heatings are used in motor vehicles e.g. for heating the air in the passenger compartment, for preheating the coolant of water-cooled engines or for heating fuel. Such auxiliary heatings normally comprise numerous heating elements, which are combined so as to form a plurality of heating stages, and a control device. The heating elements are normally implemented as an electric heating resistor, in particular as a PTC element.

A particularly advantageous PWM control can be realized by controlling the individual subloads in a phase-shifted mode so as to keep the load on the vehicle electrical system caused by periodic current fluctuations as small as possible. As is exemplarily shown in FIG. 3 for a three-stage load, the three clocked currents l_{load}_{_{—}}₁, l_{load}_{_{—}}₂, l_{load-3} are shifted for each stage by ⅓ of the period duration relative to one another. The whole load lₛᵤₘ=l_{load}_{_{—}}₁+l_{load}_{_{—}}₂+l_{load-3} can be distributed more uniformly over the whole period in this way. As can be seen in FIG. 3, the amplitude of the periodic current change (ripple current) to which the vehicle electrical system is subjected amounts to only one third (=1/n, n=number of load circuits) of the amplitude of the total current obtained by summing up the three load circuit currents. If clocking were not effected in a phase-shifted mode, but if all the load stages were switched on and off simultaneously, current fluctuations between current l=0 and the maximum current (sum current of all the load circuits) would occur in the vehicle electrical system. Another advantage of the phase-shifted control is, as can again be seen in FIG. 3, that the frequency of the ripple current has tripled (fᵣᵢₚ=n*f_{PWM})—an effect which is desirable in many cases of use. This allows, for example, to shift the frequency of the flickering of the passenger compartment illumination to a no longer noticeable frequency range.

FIG. 4 shows a conventional control device 400 in which a microcontroller (μC) 403 is used so as to realize the phase-shifted control of a plurality of load circuits R_{load}_{_{—}}₁, . . . , R_{load}_{_{—}}ₙ. The microcontroller 403 produces from an arbitrary input information, which is provided via an interface (e.g. CAN bus) 402, the various PWM signals and controls the output stages 404-1, . . . , 404-n accordingly. If the device controlled is the electric auxiliary heating, the input information may e.g. comprise the nominal heat output and the electric power available in the vehicle electrical system at the moment in question.

A disadvantage of the generation of signals for a phase-shifted control of a plurality of load circuits by means of a microcontroller is the comparatively large number of components required and the resultant costs as well as the space required by these components. Moreover, it is necessary to develop a special software for the microcontroller which is an expensive component anyhow.

A particularly simple solution for phase-shifted controlling can, for. certain applications, also be accomplished by the use of analog RC elements. A prerequisite for this is that the input signal is a PWM signal whose temporal characteristics (period duration T_{PWM} and on-time Tₒₙ) are such that it can be used directly for controlling the load circuits.

FIG. 5 shows a circuit for generating the signals for a phase-shifted control of a plurality of load circuits by RC elements. The control signal PWM is here delayed in time by (n−1) RC elements with different time constants τ₂ to τₙ and supplied to the individual output stages. For RC elements the time constant is proportional to the product R*C. The respective delay time τ₂ to τₙ is determined by the period duration T_{PWM} and the number n of load circuits. Normally, the following holds true for the individual delays and RC elements, respectively.

τ₂=T_{PWM}/n

τ₃=2*T_{PWM}/n

τ₄=3*T_{PWM}/n

τₙ=(n−1)*T_{PWM}/n

The use of analog RC elements for generating the phase-shifted PWM signals is disadvantageous with regard to the high number of discrete components required and with regard to the demands to be satisfied by the tolerances of these components. The analog solution with RC elements entails very high demands on the precision of the components of the RC elements (normal component tolerances lie between 5% and 10%, in the case of capacitors they are even wider than that) and on the precision of the circuit in the output stage, which evaluates the analog input signal PWMᵢₙ. For this circuit a Schmitt trigger is normally used, and for the present case of use this Schmitt trigger must have extremely precise and temporally stable switching thresholds. Another disadvantage is that the delay times τ₂ to τₙ must be adapted very precisely to the period duration T_{PWM} of the PWM signal PWM so as to achieve a correct phase shift of the individual signals. Conversely, the fact that the period duration and the delay time are linked results in corresponding demands on the control device which generates the PWM signal. Also there the frequency of the PWM signal must be observed in a very precise and stable manner (without drift). Such demands on PWM signals can, however, only be realized with a correspondingly high investment in circuit technology. The magnitude evaluated in a PWM control is, moreover, not the frequency of the PWM signal, but only the duty cycle. Frequency deviations should therefore be admissible.

### SUMMARY OF THE INVENTION

It is therefore the object of the present invention to provide an improved circuit for generating the phase-shifted PWM signals. Another object of the present invention is to provide an integrated semiconductor switch on the basis of which the circuit for generating the phase-shifted PWM signals can be realized at a reasonable price. In addition, it as also an object of the present invention to provide a control device and a corresponding method which allows an improved PWM control of a multi-stage electric load.

These objects are achieved by the features of the independent claims. Preferred embodiments are the subject matter of the dependent claims.

It is the particular approach of the present invention to provide an output stage for PWM control of a load stage with a delay circuit which, in addition to the load current modulated by a PWM input signal, supplies a PWM output signal that is delayed by a predetermined fraction of the period duration relative to the PWM input signal.

According to a first aspect of the present invention, an output stage for pulsewidth-modulated control of an electric load is provided. This output stage comprises a first input for inputting a first pulsewidth modulation signal, a power semiconductor switch for controlling the electric load according to the duty cycle of the first pulsewidth modulation signal, a delay circuit for generating a second pulsewidth modulation signal which is delayed relative to the first pulsewidth modulation signal, and a signal output for outputting the second pulsewidth modulation signal, and said output stage is characterized in that the delay circuit comprises a first detector circuit, which detects the period duration of the first pulsewidth modulation signal and generates the second pulsewidth modulation signal such that it is delayed relative to the first pulsewidth modulation signal by a predetermined fraction of the period duration detected.

According to an advantageous embodiment, the delay circuit is configured such that the second pulsewidth modulation signal is delayed relative to the first pulsewidth modulation signal by a predetermined value, preferably by a fraction of the period duration of the first pulsewidth modulation signal. It is thus possible to control several stages of an electric load in a simple maimer by means of PWM signals having a fixed time- or phase-shift. Preferably, it is also possible to represent the fraction of the period duration by a unit fraction. All the necessary phase-shifts for controlling a multi-stage load can then be produced by cascading the delay circuits.

The output stage according to claim 1 preferably comprises a second input for inputting a control signal, the delay circuit being configured such that the second pulsewidth modulation signal is delayed relative to the first pulsewidth modulation signal by a value which is determined by the control signal. This allows the time-shift of the PWM signals to be adapted to the number of stages and to be predetermined externally.

The delay circuit preferably comprises a first detector circuit, which detects the period duration of the first pulsewidth modulation signal and generates the second pulsewidth modulation signal such that it is delayed relative to the first pulsewidth modulation signal by a fraction of the period duration detected, said fraction being determined by the control signal. Preferably, the first detector circuit is also configured such that the period duration is detected during a period of the first pulsewidth modulation signal. In addition, the delay circuit preferably comprises a second detector circuit, which detects the on-time of the first pulsewidth modulation signal and generates the second pulsewidth modulation signal such that it has the on-time detected. According to an advantageous embodiment, the second detector circuit is configured such that the on-time is detected during a period of the first pulsewidth modulation signal. It is thus possible to indicate, instead of a shift time, the phase-shift directly. The delayed PWM signal is then automatically generated with the correct timing parameters.

Problems with regard to the accuracy of the time base used and/or fluctuations in the input frequency are avoided as well.

The power semiconductor switch is preferably a MOSFET (Metal Oxide Semiconductor Field Effect Transistor). Such power semiconductor switches have excellent manufacturing and switching properties.

The power semiconductor switch and the delay circuit are preferably monolithically integrated on a semiconductor chip or they are realized on two separate semiconductor chips which are integrated in a common housing. The output stage according to the present invention is preferably provided with an additional circuit for controlling the power semiconductor switch. The control circuit can, in particular, comprise a charge pump so as to generate a gate voltage for controlling the MOSFET, which is higher than the operating voltage. The additional circuit may also comprise a circuit for protecting the power semiconductor switch against overload. It will also be advantageous to integrate the delay circuit and the additional circuit on a common semiconductor chip. This will allow an easy manufacture and a flexible use of the output stage according to the present invention.

According to a second aspect of the present invention, a controller for pulsewidth-modulated control of an electric load comprising a plurality of electrically independent load stages is provided. The controller comprises a first output stage according to the present invention for controlling a first load stage of the electric load in accordance with a predetermined first pulsewidth modulation signal and for outputting a second pulsewidth modulation signal which is delayed relative to said first pulsewidth modulation signal, and a second output stage for controlling a second load stage of the electric load in accordance with the second pulsewidth modulation signal.

The first and the second output stages belong preferably to a plurality of output stages according to the present invention, which are interconnected in a cascaded fashion and which are each associated with a load stage of the electric load. According to an advantageous embodiment, each of the cascaded output stages outputs a pulsewidth modulation signal which, in comparison with the inputted pulsewidth modulation signal, is shifted by a fraction of the period duration that corresponds to the number of load stages of the electric load. It is thus possible to control a multi-stage load with phase-shifted PWM signals so that the current load is uniformly distributed over the PWM period duration. This will avoid load peaks as well as a simultaneous switching of a plurality of load stages.

According to a third aspect of the present invention, a method for pulsewidth-modulated controlling of an electric load with a plurality of electrically independent stages is provided. This method comprises the steps of cascading a plurality of output stages according to the present invention, each of said output stages controlling a stage of the electric load; generating a pulsewidth modulation signal; and feeding the pulsewidth modulation signal at the first output stage of the cascaded plurality of output stages.

In the following, the present invention will be described with reference to the enclosed figured, in which:

### BRIEF DESCRIPTION OF THE DRAWINGS

FIG. 1 shows a schematic representation of pulsewidth modulation,

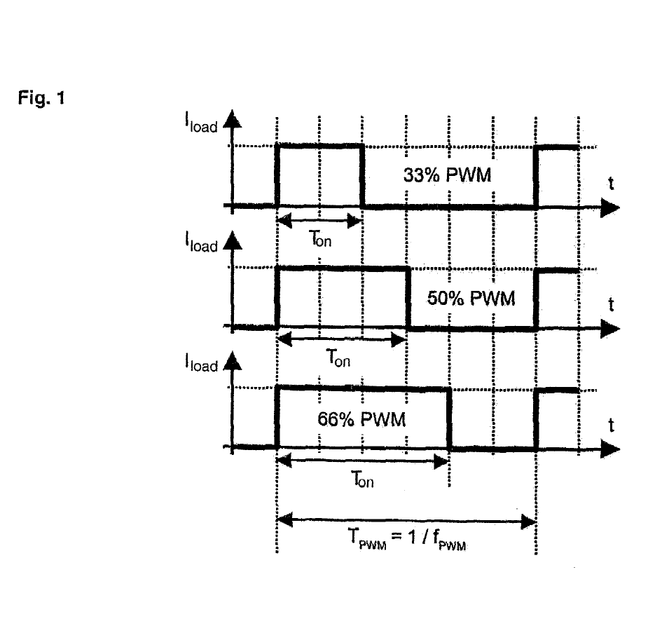

FIG. 2 shows a schematic representation of a conventional output stage,

FIG. 3 shows a schematic representation of the signals for phase-shifted PWM controlling of a multi-stage load,

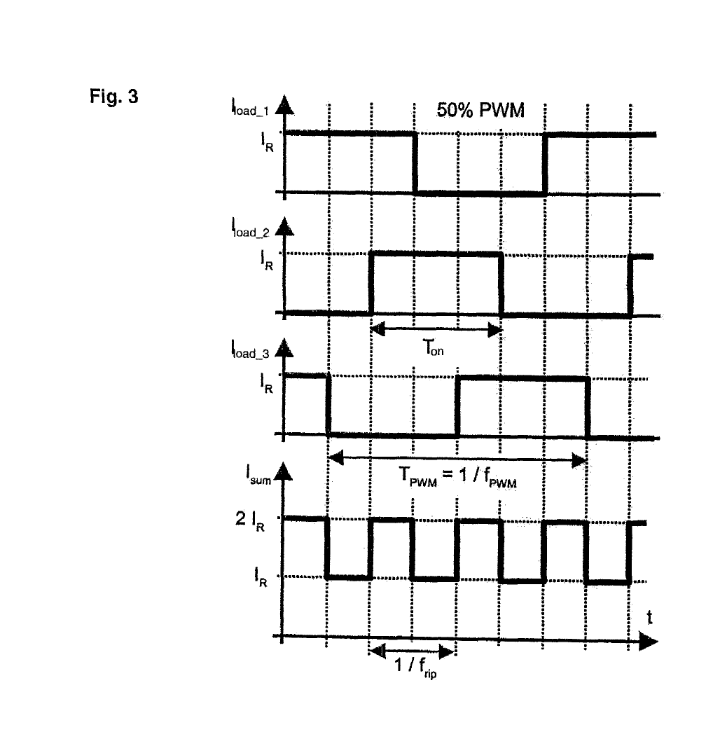

FIG. 4 shows schematically a conventional circuit for generating the phase-shifted signals by a microcontroller,

FIG. 5 shows schematically a conventional circuit for generating the phase-shifted signals by RC elements,

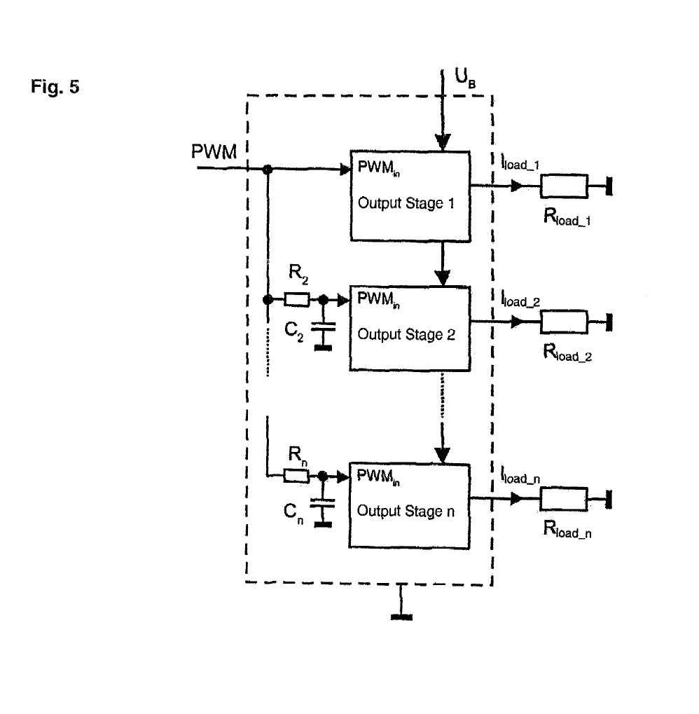

FIG. 6A shows schematically the structural design of a PWM output stage according to an embodiment of the present invention,

FIG. 6B shows schematically the structural design of the PWM delay circuit of the PWM output stage of FIG. 6A according to an embodiment of the present invention,

FIG. 7 shows schematically the structural design of a controller for pulsewidth-modulated controlling of a multi-stage electric load according to an embodiment of the present invention,

FIG. 8 shows the generation of the delayed PWM signal by the PWM delay circuit according to the present invention, and

FIG. 9 shows schematically the structural design of the integrated semiconductor switch according to a further embodiment of the present invention.

### DETAILED DESCRIPTION OF THE PREFERRED EMBODIMENT

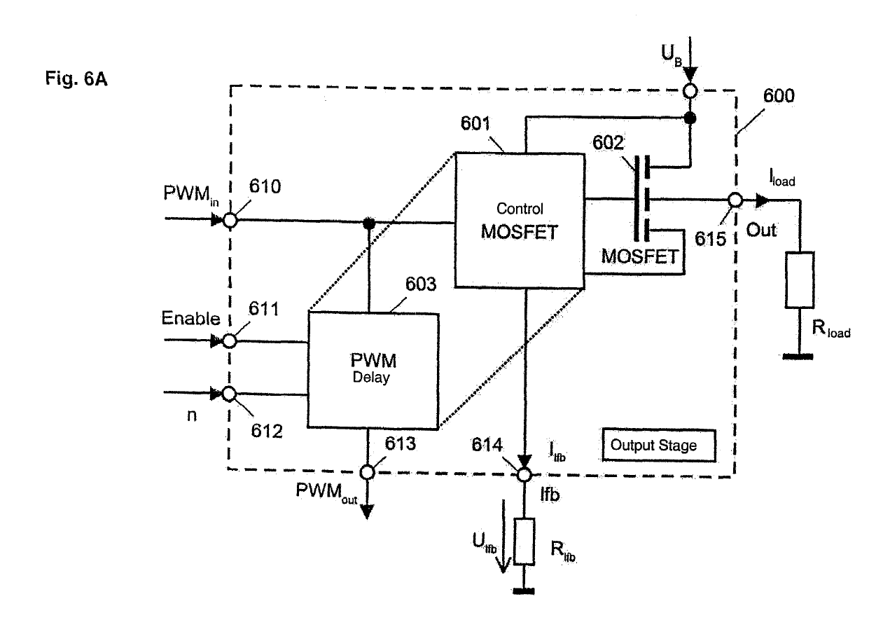

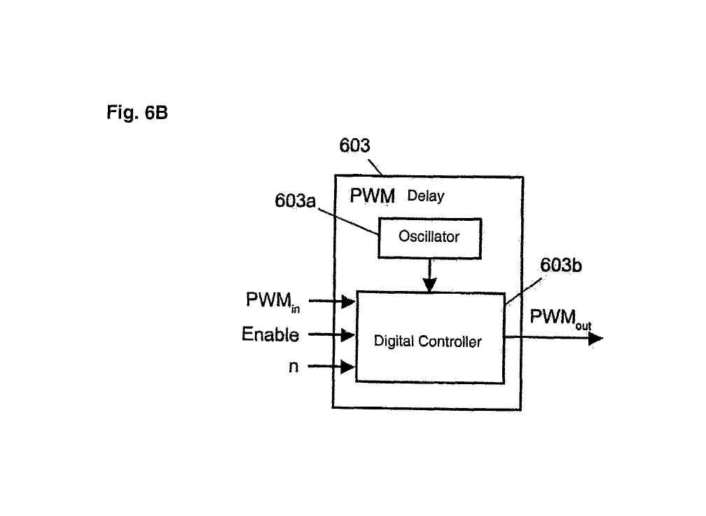

FIG. 6A shows an output stage for PWM control of a load according to an embodiment of the present invention. The load R_{load} is connected to the supply voltage U_{B} through a power semi-conductor switch 602, preferably a MOSFET. The load current l_{load} is modulated by the control circuit 601 in accordance with the external PWM signal PWMᵢₙ. The control circuit 601 can execute additional monitoring functions and protect the power semiconductor switch 602 against overload. The control circuit 601 can e.g. monitor the temperature of the power semi-conductor switch 602 and/or the switched current. If predetermined limit values are exceeded, the control circuit can switch off the semiconductor switch. In addition, a feedback signal l_{lfb}, used as a measure for the load current l_{load} detected by a current sensor, can be provided at a terminal lfb for an extended external control.

The output stage according to the present invention is additionally provided with a PWM delay circuit 603, which generates a PWM signal PWMₒᵤₜ that is delayed relative to the PWM input signal PWMᵢₙ. The delay period Tᵥ is determined by the period duration T_{PWM} of the PWM input signal PWMᵢₙ and a control signal n:

Tᵥ=T_{PWM}/n,

wherein n preferably is an integer larger than 1, in particular n=2, 3, 4, 5, 6 or 8. It follows that the ratio n of the delay period Tᵥ to the period duration T_{PWM} can be represented by a unit fraction (i.e. a fraction whose numerator=1).

The control signal n is predetermined preferably externally in digital form; different embodiments of the control signal terminal are possible. In the simplest case, the control signal terminal consists of one or more digital signal line(s) which has/have applied thereto the divisional ratio n through respective digital signal levels. Alternatively, it is, however, also possible to use any other parallel or serial interface.

The control signal n can, however, also be generated within the output stage, especially when the output stage is realized as an integrated component. The value of the control signal n can in this case be predetermined by programming during the production of the component (e.g. Zener zapping) or by suitable different bonds between the external terminals and the silicon chip.

Furthermore, the output stage can be provided with an “enable” input which has applied thereto a digital enable signal. By means of the enable input signal, the function of the block “PWM delay” 603 is activated and deactivated, respectively. The enable function can also be realized as connection or disconnection of the supply voltage U_{B} for the circuit blocks “Control MOSFET” 601 and “PWM Delay” 603.

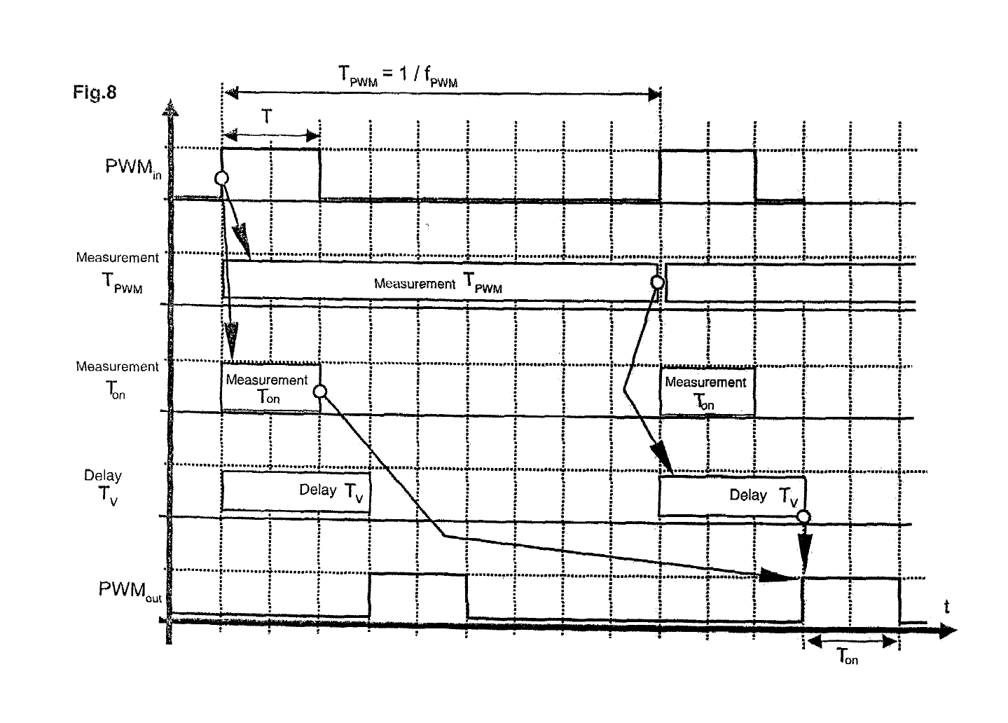

FIG. 6B shows the structural design of the PWM delay circuit 603 according to one embodiment of the present invention. The input signals PWMᵢₙ, enable and n arrive at a digital control unit 603b which generates and outputs the output signal PWMₒᵤₜ. The PWM delay circuit 603 additionally comprises an internal oscillator 603a which provides the digital control unit 603b with a clock signal. The function of the control unit will be described hereinbelow in more detail in connection with FIG. 8.

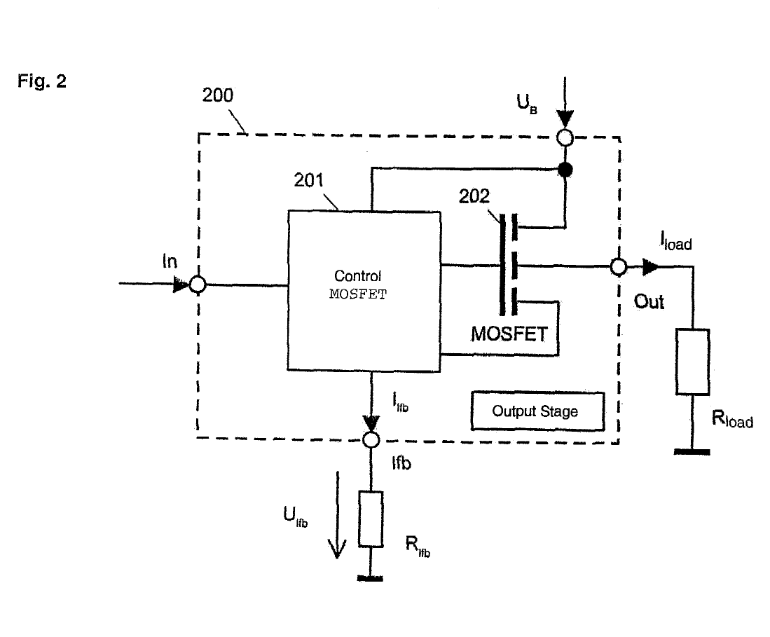

The output stage 600 according to the present invention, which is shown in FIG. 6A and 6B, is preferably realized as an integrated circuit. The output stage according to the present invention can, in particular, be realized by extending the control and monitoring circuit 201, which is included in the conventional output stage 200 according to FIG. 2 anyway, by an additional circuit block “PWM Delay”. Preferably, also this circuit block will be accommodated in the housing of the output stage, and preferably also together with the block “Control MOSFET” 601 on a common semiconductor chip (cf. the broken lines in FIG. 6). This allows a particularly efficient production of the output stage according to the present invention.

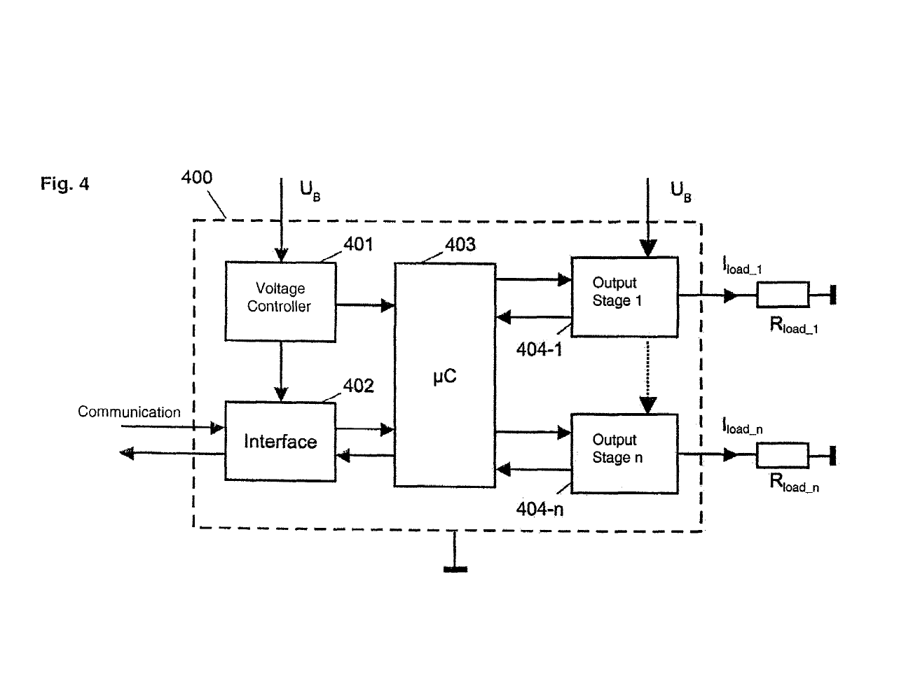

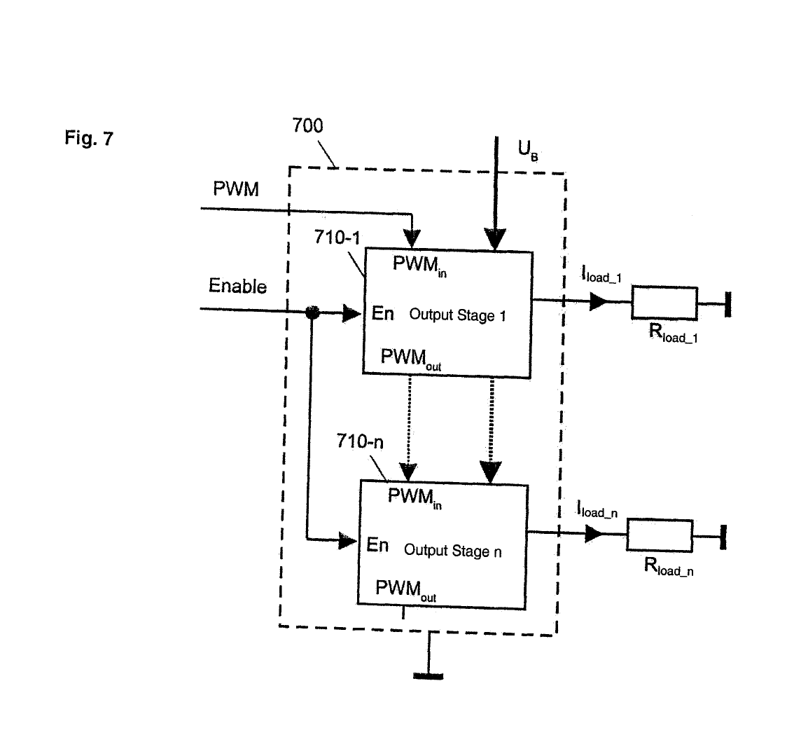

FIG. 7 shows a controller according to an embodiment of the present invention for controlling a multi-stage load. The controller 700 controls the load circuits R_{load}_{_{—}}₁, . . . , R_{load}_{_{—}}ₙ with pulsewidth-modulated load currents l_{load-1}, . . . , l_{load}_{_{—}}ₙ, the respective load currents being temporally delayed relative to one another by the magnitude Tᵥ=T_{PWM}/n. The controller 700 essentially consists of n output stages 710-1, . . . 710-n according to the present invention, of the type described hereinbefore in connection with FIG. 6. The individual output stages 710-1, . . . 710-n are sequentially connected (cascaded) so that the delayed PWM signal outputted by one output stage serves as input signal for the respective next output stage. Hence, only a single PWM signal has to be generated externally; the majority of the delayed PWM signals is generated by the cascaded output stages themselves. It follows that, in comparison with the prior art, cf. FIG. 4, the number of components for the controller for controlling n load circuits is reduced to n output stages with an extended functionality according to the present invention.

In addition to the external PWM signal, the controller can optionally have supplied thereto an enable signal, which is equally applied to all the output stages of the controller. The control signal n (not shown in FIG. 7), which determines the magnitude of the delay relative to the period duration of the PWM signal, is also equal for all the output stages and can be generated in the controller itself, e.g. by setting to the associated digital inputs of the output stages to the respective logic levels.

In the controller according to FIG. 7, the PWM signal output of the last output stage 710-n is open, since for controlling n load stages only (n−1) delay circuits are needed. Hence, the last output stage 710-n can also be replaced by a conventional output stage without any delay circuit, of the type shown in FIG. 2.

FIG. 8 is a diagram on the basis of which the mode of operation of the digital control unit 603b according to FIG. 6B will be explained hereinbelow.

Within each PWM period T_{PWM}, the PWM input signal PWMᵢₙ is measured on the one hand, and, on the other hand, the PWM output signal is generated according to the measurement results of the preceding period. In detail, the following steps are executed by the control unit:
(1) measuring the PWM input signal PWMᵢₙ(with the period duration T_{PWM} and the on-time Tₒₙ) with regard to T_{PWM} and Tₒₙ and storing the values,
(2) determining the delay time Tᵥ, which depends on the control signal n and on the number n of load circuits, respectively, and with which the PWM input signal is to be outputted at the output PWMₒᵤₜ: Tᵥ=T_{PWM}/n,
(3) after expiration of the clock cycle T_{PWM} of the signal PWMᵢₙ, starting the delay time Tᵥ, and
(4) after expiration of the delay time Tᵥ, activating the output signal PWMₒᵤₜ for the time Tₒₙ.

The digital control unit 603b can be realized by a suitable interconnection of conventional logic gates. The period duration T_{PWM} and the on-time Tₒₙ can be determined e.g. with the aid of a binary counter driven by the oscillator 603a, and stored in a latch. The control unit preferably includes a further register in which the delay Tᵥ calculated on the basis of the period duration ascertained and on the basis of the control signal n is stored. Also the output signal PWMₒᵤₜ can be generated by means of a binary counter driven by the oscillator and by means of a comparator which compares the counter reading with the stored register values.

Both the measurement of the input signal PWMᵢₙ and the generation of the output signal PWMₒᵤₜ take place relative to the clock signal generated by the oscillator 603a. The problems arising with respect to the accuracy and the stability of the time base in conventional controllers for phase-shifted control of a plurality of load circuits are solved in this way. In particular, a calibration of the time base (e.g. in milliseconds or the like) can be dispensed with, since the precise value of the clock frequency of the oscillator 603a is of no importance to the generation of the output signal. If at all, it is only the granularity in the determination of the delay time Tᵥ and of the on-time Tₒₙ which depends on the selection of the clock frequency.

In practice, PWM signals having a frequency of a few 10 Hz to 1 kHz are used so that clock frequencies of 10 kHz to 1 MHz will suffice for a sufficient temporal resolution.

In addition, the measurement of the input signal is repeated in each PWM period. Hence, precautions for stabilizing the oscillator frequency against (thermal) drift are not necessary, since drift-dependent changes of the oscillator frequency occur on a time scale which is markedly slower than the period duration of the pulsewidth modulation.

Finally, it is not necessary to adapt the delay time to the period duration of the pulsewidth modulation, since the output stage according to the present invention requires as input information only the number of stages to be controlled in a phase-shifted manner, and since the output stage itself then calculates, on the basis of this information, the necessary delay time in dependence upon the period duration measured. This even allows the controller according to the present invention to react to variations in the frequency of the external PWM signal.

In the above-described embodiments of the PWM output stage according to the present invention, a digital control unit is used for generating the delayed PWM signal PWMₒᵤₜ. The present invention is, however, not limited to a digital generation of the delayed PWM signal PWMₒᵤₜ, but it is also possible to use an analog circuit, e.g. with a PLL (phase locked loop).

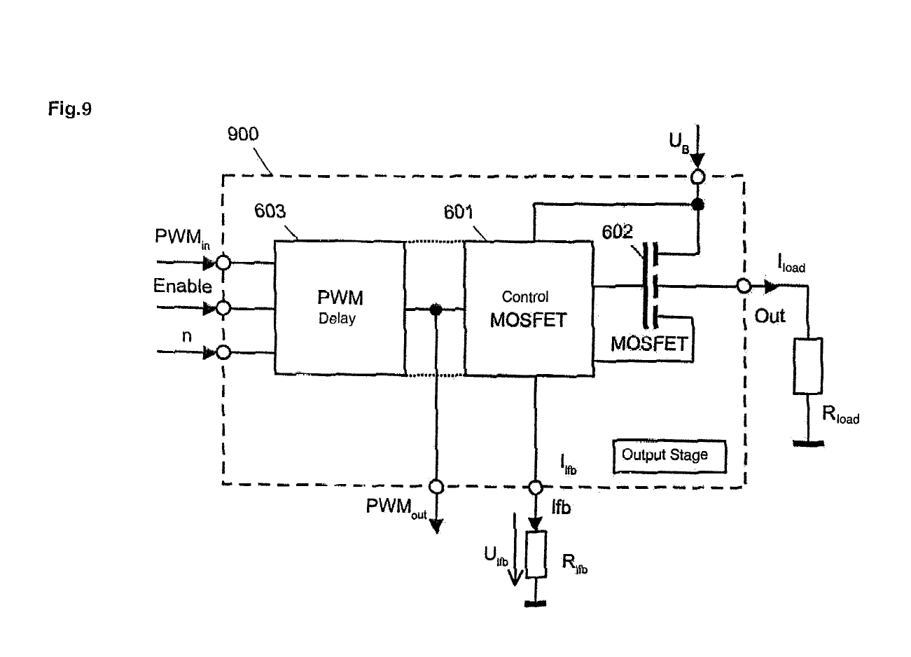

FIG. 9 shows the structural design of an alternative output stage according to the present invention. The output stage of FIG. 9 differs from the output stage according to FIG. 6A only insofar as the control circuit 601 is driven by the delayed PWM signal PWMₒᵤₜ and not by the PWM input signal PWMᵢₙ. As for the rest, the elements designated by identical reference numerals in FIG. 6A and 9 also have identical functions whose renewed detailed description is here not necessary.

Summarizing, it can be stated that for controlling a multi-stage load with pulsewidth modulation (PWM), the individual stages have normally separately applied thereto load currents which are clocked in a phase-shifted mode so as to avoid load peaks. Conventional controllers used for phase-shifted PWM control are, however, characterized by a high complexity and/or problems arising with respect to the temporal precision of the clocking of the individual load currents. Hence, it is the particular approach of the present invention to provide an output stage for PWM control of a load stage with a delay circuit which, in addition to the load current modulated by a PWM input signal, supplies a PWM output signal that is delayed by a predetermined fraction of the period duration relative to the PWM input signal. The output stage according to the present invention can especially be realized by integrating the delay circuit together with the actual power semiconductor switch and an associated monitoring and control circuit in a single component. By cascading such output stages, a controller for phase-shifted PWM control, which is independent of a precise time base, can be realized in a simple manner.

1. An output stage for pulsewidth-modulated control of an electric load, said output stage comprising:
a first input for inputting a first pulsewidth modulation signal;
a power semiconductor switch for controlling the electric load according to the duty cycle of the first pulsewidth modulation signal;
a delay circuit for generating a second pulsewidth modulation signal which is delayed relative to the first pulsewidth modulation signal; and
a signal output for outputting the second pulsewidth modulation signal,
wherein
the delay circuit comprises a first detector circuit which detects the period duration of the first pulsewidth modulation signal and which generates the second pulsewidth modulation signal such that it is delayed relative to the first pulsewidth modulation signal by a predetermined fraction of the detected period duration.

2. An output stage according to claim 1, wherein the predetermined fraction of the period duration can be represented by a unit fraction.

3. An output stage according to claim 1, further comprising a second input for inputting a control signal, wherein the delay circuit is configured such that the second pulsewidth modulation signal is delayed relative to the first pulsewidth modulation signal by a fraction of the detected period duration, said fraction being set by the control signal.

4. An output stage according to claim 1, wherein the first detector circuit is configured such that the period duration is detected during one period of the first pulsewidth modulation signal.

5. An output stage according to claim 1, wherein the delay circuit comprises a second detector circuit which detects the on-time of the first pulsewidth modulation signal and which generates the second pulsewidth modulation signal such that the second pulsewidth modulation signal has the detected on-time.

6. An output stage according to claim 5, wherein the second detector circuit is configured such that the on-time is detected during one period of the first pulsewidth modulation signal.

7. An output stage according to claim 1, wherein the power semiconductor switch is a MOSFET.

8. An output stage according to claim 1, wherein the power semiconductor switch and the delay circuit are monolithically integrated on a semiconductor chip.

9. An output stage according to claim 1, wherein the power semiconductor switch and the delay circuit are realized on two separate semiconductor chips which are integrated in a common housing.

10. An output stage according to claim 1, further comprising an additional circuit for controlling the power semiconductor switch.

11. An output stage according to claim 10, wherein the additional circuit further comprises a circuit for protecting the power semiconductor switch against overload.

12. An output stage according to claim 10, wherein the delay circuit and the additional circuit are integrated on a common semiconductor chip.

13. A controller for pulsewidth-modulated control of an electric load comprising a plurality of electrically independent load stages, wherein said controller comprises:
a first output stage for controlling a first load stage of the electric load in accordance with a predetermined first pulsewidth modulation signal and for outputting a second pulsewidth modulation signal which is delayed relative to said first pulsewidth modulation signal; and
a second output stage for controlling a second load stage of the electric load in accordance with the second pulsewidth modulation signal, wherein
the first output stage includes:
a first input for inputting a first pulsewidth modulation signal;
a power semiconductor switch for controlling the electric load according to the duty cycle of the first pulsewidth modulation signal;
a delay circuit for generating a second pulsewidth modulation signal which is delayed relative to the first pulsewidth modulation signal; and
a signal output for outputting the second pulsewidth modulation signal,
wherein
the delay circuit comprises a first detector circuit which detects the period duration of the first pulsewidth modulation signal and which generates the second pulsewidth modulation signal such that it is delayed relative to the first pulsewidth modulation signal by a predetermined fraction of the detected period duration.

14. A controller according to claim 13, wherein the second output stage a first input for inputting a first pulsewidth modulation signal;
a power semiconductor switch for controlling the electric load according to the duty cycle of the first pulsewidth modulation signal;
a delay circuit for generating a second pulsewidth modulation signal which is delayed relative to the first pulsewidth modulation signal; and
a signal output for outputting the second pulsewidth modulation signal,
wherein
the delay circuit comprises a first detector circuit which detects the period duration of the first pulsewidth modulation signal and which generates the second pulsewidth modulation signal such that it is delayed relative to the first pulsewidth modulation signal by a predetermined fraction of the detected period duration.

15. A controller according to claim 13, wherein the first and the second output stages belong to a plurality of output stages which are interconnected in a cascaded fashion and which are each associated with a load stage of the electric load.

16. A controller according to claim 15, wherein each of the cascaded output stages outputs a pulsewidth modulation signal which, in comparison with the inputted pulsewidth modulation signal, is shifted by a fraction of the period duration that corresponds to the number of load stages of the electric load.

17. A method for pulsewidth-modulated controlling of an electric load with a plurality of electrically independent stages, said method comprising:
cascading a plurality of output stages, each of said output stages controlling a stage of the electric load;
generating a pulsewidth modulation signal; and
feeding the pulsewidth modulation signal at the first output stage of the cascaded plurality of output stages, wherein
each of the output stages includes:
a first input for inputting a first pulsewidth modulation signal;
a power semiconductor switch for controlling the electric load according to the duty cycle of the first pulsewidth modulation signal;
a delay circuit for generating a second pulsewidth modulation signal which is delayed relative to the first pulsewidth modulation signal; and
a signal output for outputting the second pulsewidth modulation signal,
wherein
the delay circuit comprises a first detector circuit which detects the period duration of the first pulsewidth modulation signal and which generates the second pulsewidth modulation signal such that it is delayed relative to the first pulsewidth modulation signal by a predetermined fraction of the detected period duration.

18. A method according to claim 17, wherein, during cascading of the plurality of output stages, the signal output of an output stage is connected to the first input of the next output stage.

19. A method according to claim 17, further comprising feeding, at each output stage, a control signal which is indicative of the number of stages of the electric load.
